(19) United States
(12) Patent Application Publication
(10) Pub. No.: US 2009/0187359 A1
(43) Pub. Date: Jul. 23, 2009

(54) SYSTEM AND METHOD FOR ESTIMATING BATTERY STATE OF CHARGE

(75) Inventors: Rush Winslow Hood, Tampa, FL (US); Charles Edmund Murphy, Sarasota, FL (US)

Correspondence Address: PETER VOGEL;GE HEALTHCARE, 20225 WATER TOWER BLVD., MAIL STOP W492, BROOKFIELD, WI, 53045, US

(73) Assignee: GENERAL ELECTRIC COMPANY, Schenectady, NY (US)

(21) Appl. No.: 12/016,683

(22) Filed: Jan. 18, 2008

(51) Int. Cl. G01R 31/36; G06F 19/00; H01M 10/48

(52) U.S. Cl. 702/63; 324/426

(57) ABSTRACT

A battery system is disclosed herein. The battery system includes a battery and a controller operatively connected to the battery. The controller is configured to estimate a battery state of charge based on a history of the battery current such that the battery state of charge estimate is obtainable during the battery's course of use. A corresponding method for estimating the state of charge of a battery is also disclosed.

### BACKGROUND OF THE INVENTION

The subject matter disclosed herein relates to a system and method adapted to estimate a battery's state of charge.

Battery state of charge (SOC) generally refers to the battery's remaining capacity. Knowing the amount of energy left in a battery gives the user an indication of how much longer a battery will continue to perform before it needs to be recharged or replaced. This information may be particularly important for applications in which excessive battery depletion must be avoided to ensure the device remains fully operational at all times.

There are several methods and systems for estimating SOC. One problem is that variables such as the rate at which the battery has been charged or discharged over time can introduce imprecision into conventional methods for estimating SOC. Another problem is that some conventional methods for estimating SOC require a steady state condition wherein the battery has not been charged or discharged for a period of several hours. It can be seen that these methods are not optimal for implementation with systems in which the battery is frequently being either charged or discharged, or being charged or discharged with a varying current.

### BRIEF DESCRIPTION OF THE INVENTION

The above-mentioned shortcomings, disadvantages and problems are addressed herein which will be understood by reading and understanding the following specification.

In an embodiment, a battery system includes a battery and a controller operatively connected to the battery. The controller is configured to estimate a battery state of charge based on a history of the battery current such that the battery state of charge estimate is obtainable during the battery's course of use.

In another embodiment, a patient monitoring system includes a battery, a patient monitoring device operatively connected to the battery, and a controller operatively connected to the battery. The controller is configured to estimate a battery state of charge based on a recently acquired battery terminal voltage measurement; a recently acquired battery terminal current measurement; and a history of the battery current. The battery state of charge estimate is obtainable during the battery's course of use.

In another embodiment, a method for estimating the state of charge of a battery includes obtaining a recently acquired battery terminal voltage measurement, obtaining a recently acquired battery terminal current measurement, and obtaining a history of the battery current. The method also includes estimating a source voltage based on the recently acquired battery terminal voltage measurement, the recently acquired battery terminal current measurement, and the history of the battery current. The method also includes estimating a battery state of charge based on the source voltage such that the battery state of charge is obtainable during the battery's course of use.

Various other features, objects, and advantages of the invention will be made apparent to those skilled in the art from the accompanying drawings and detailed description thereof.

### BRIEF DESCRIPTION OF THE DRAWINGS

FIG. 1 is a schematic representation of a system in accordance with an embodiment;

FIG. 2 is a schematic illustration of a battery model in accordance with an embodiment;

FIG. 3 is a schematic illustration of a battery model in accordance with an embodiment;

FIG. 4 is an exemplary plot of battery terminal voltage versus state of charge;

FIG. 5 is a flowchart illustrating a method in accordance with an embodiment;

FIG. 6 is a graph including a voltage versus time plot and a remaining capacity versus time plot;

FIG. 7 is a graph including two voltage versus time plots and a remaining capacity versus time plot; and

FIG. 8 is a graph including two voltage versus time plots and a remaining capacity versus time plot.

### DETAILED DESCRIPTION OF THE INVENTION

In the following detailed description, reference is made to the accompanying drawings that form a part hereof, and in which is shown by way of illustration specific embodiments that may be practiced. These embodiments are described in sufficient detail to enable those skilled in the art to practice the embodiments, and it is to be understood that other embodiments may be utilized and that logical, mechanical, electrical and other changes may be made without departing from the scope of the embodiments. The following detailed description is, therefore, not to be taken as limiting the scope of the invention.

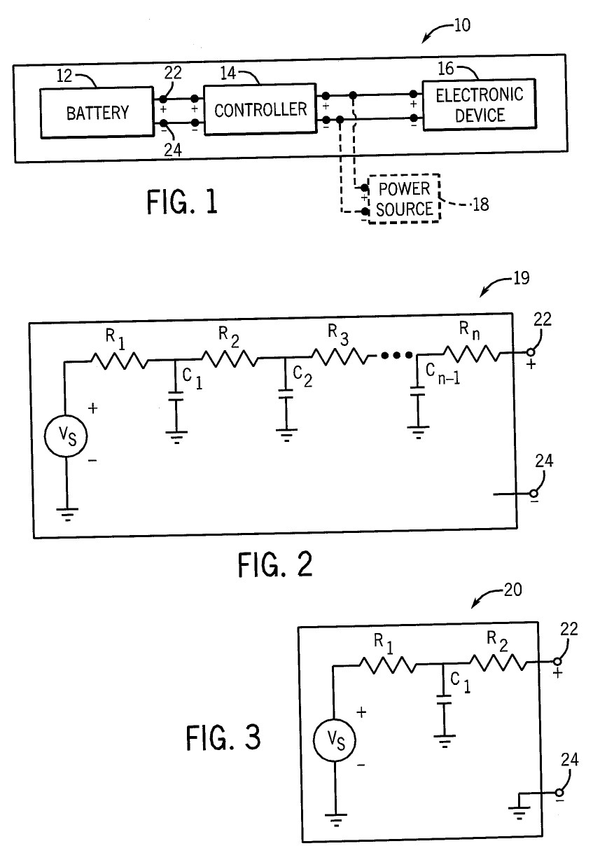

Referring to FIG. 1, a system 10 is shown in accordance with one embodiment. The system 10 includes a battery 12, a controller 14, and an electronic device 16. The battery 12 may comprise a lead-acid battery. The electronic device 16 may comprise a portable patient monitoring device adapted to monitor one or more vital signs such as temperature, pulse rate, blood pressure and respiratory rate. It should, however, be appreciated that the system 10 may alternatively include other types of batteries and other electronic devices.

According to one embodiment, the battery 12 is electrically coupled to the controller 14, and the controller 14 is electrically coupled to the electronic device 16. Energy from the battery 12 is transferable through the controller 14 and to the electronic device 16 in order to power the electronic device 16. When the battery 12 becomes depleted, it may be re-charged by an external power source 18.

The controller 14 is connected to the positive terminal 22 and the negative terminal 24 of the battery 12, and is configured to measure battery terminal voltage Vₜ and/or battery terminal current Iₜ at the terminals 22, 24 in a known manner. As will be described in detail hereinafter, the controller 14 is also configured to estimate the state of charge (SOC) of the battery 12 during the battery's course of use. For purposes of this disclosure, SOC refers to a battery's remaining capacity, and a battery's course of use includes periods wherein the battery is charging, discharging, and/or idle. The battery SOC estimate can be transferred from the controller 14 to the electronic device 16 for communication to a user.

The controller 14 may estimate battery SOC based on an equation derived from a battery model 19, which is shown in FIG. 2 in accordance with an embodiment. The battery model 19 comprises an electric circuit driven by an internal voltage source Vs, and is adapted to describe the electrochemical behavior of the battery 12 (shown in FIG. 1). According to one embodiment, the electronic circuit of the battery model 19 includes a plurality of resistors R₁-Rₙ disposed in series, and a corresponding plurality of capacitors C₁-Cₙ₋₁ that are each disposed between an adjacent pair of resistors. The resistors R₁-Rₙ and the capacitors C₁-Cₙ₋₁ respectively represent an internal battery resistance and an internal battery capacitance inherent in many different types of battery. The number of resistors and capacitors can be increased to improve the precision with which the battery model 20 describes the behavior of the battery 12. According to another embodiment, the battery model 19 may comprise inductances in place of or in addition to the capacitors C₁-Cₙ₋₁.

Referring to FIG. 3, a simplified battery model 20 is shown in accordance with an embodiment. The battery model 20 comprises a single capacitor C₁ disposed between a pair of resistors R₁ and R₂. The embodiment of the battery model 20 depicted in FIG. 3 will hereinafter be described for illustrative purposes, however, it should be appreciated by one skilled in the art that alternate embodiments comprising additional resistors and capacitors may be implemented in a similar manner.

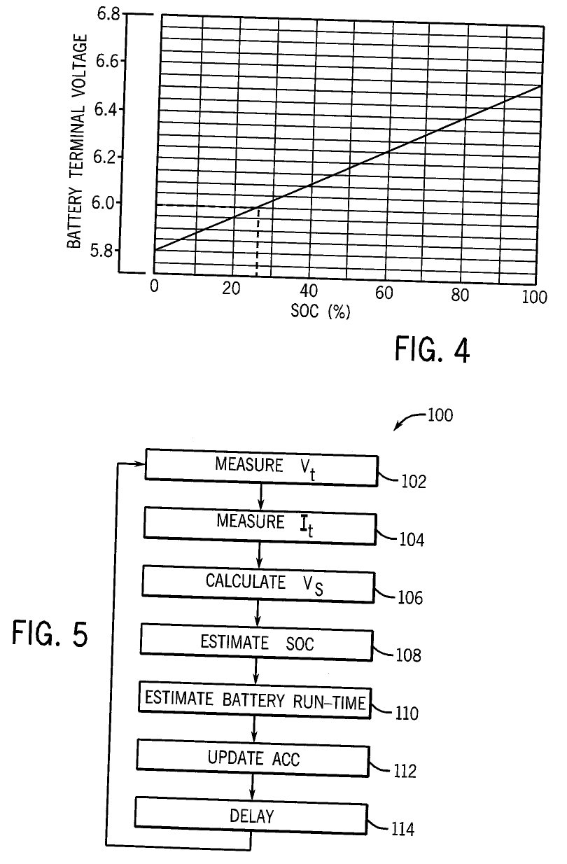

It is well known that battery terminal voltage Vₜ can be used to estimate battery SOC if the battery has been idle (i.e., not charged or discharged) for a period of time. One way of obtaining a battery SOC estimate based on measured battery terminal voltage Vₜ is by using a plot such as that shown in FIG. 4. The plot of FIG. 4 correlates battery terminal voltage with battery SOC and is available from the manufacturer or by compiling test data acquired over a range of battery terminal voltage values. As an example, if the battery has been idle for a sufficiently long period of time, a measured battery terminal voltage of 6.0V would indicate an approximately 28% SOC. In other words, it can be estimated that approximately 28% of the battery's capacity remains based on a battery terminal voltage measurement of 6.0V. One problem with the previously described method is that it may be necessary to wait while the battery remains idle for a period of several hours before an accurate estimation of battery SOC can be obtained.

Referring again to FIG. 3, it can be seen that the internal voltage source Vₛ is generally equivalent to battery terminal voltage Vₜ when the battery has been idle for a period of time. In other words, after the capacitor C₁ reaches voltage level Vₛ and there has not been any current passing through the resistors R₁ and R₂ for a period of time, the voltage at the internal source Vₛ is generally equivalent to the voltage at the terminals Vₜ. Accordingly, calculated Vₛ values may be implemented in combination with a plot similar to that of FIG. 4 to estimate battery SOC in a manner that does not require the battery to remain idle. If the load current is known or can be estimated, the remaining battery run-time can also be calculated based on battery SOC. The following will describe a method for calculating Vₛ such that battery SOC and/or battery run-time can be estimated.

Referring to FIGS. 1 and 3, the controller 14 is configured to calculate Vₛ based on recently acquired battery terminal voltage Vₜ and battery terminal current Iₜ measurements, as well as a history of the battery current. For purposes of this disclosure, the history of the battery current comprises one or more previously acquired battery terminal current Iₜ measurements. Also for purposes of this disclosure, a recently acquired measurement is one obtained generally simultaneously with its intended use (e.g., within the preceding 5 seconds), and a previously acquired measurement is one obtained more than 30 seconds before its intended use. According to one embodiment, the controller 14 may be configured to calculate Vₛ using the equation: Vₛ=Vₜ−(R₂*Iₜ)−(ACC*R₁*(1/B_{tc}) derived from the model 20. A method implementing this equation to estimate battery SOC and/or battery run-time will now be described.

Referring to FIG. 5, a flow chart illustrating a method 100 for estimating SOC and/or battery run-time is shown in accordance with an embodiment. The individual blocks 102-114 represent steps that may be performed by the controller 14 (shown in FIG. 1). Those skilled in the art will recognize that the steps 102-114 may be rearranged and/or combined in ways that preserve the underlying computation.

Referring to FIGS. 3 and 5, at step 102, battery terminal voltage Vₜ is measured at the terminals 22, 24 in a known manner. At step 104, battery terminal current Iₜ is measured at the terminals 22, 24 in a known manner.

At step 106, the internal voltage source Vₛ is calculated using the equation: Vₛ=Vₜ−(R₂*Iₜ)−(ACC*R₁*(1/B_{tc}). An exemplary method for calculating Vₛ according to the preceding equation will hereinafter be described in detail. At step 108, battery SOC is estimated. According to one embodiment, battery SOC may be estimated using the calculated value of Vₛ obtained at step 106 and the method previously described with respect to FIG. 4. At step 110, battery run-time is estimated. According to one embodiment, battery run-time may be estimated based on SOC obtained at step 108 and a generally worst-case current draw value. For example, if the most demanding operation of the electronic device 16 (shown in FIG. 1) draws battery current at a rate of 0.75 amps, this value may be used in combination with battery SOC to provide a run-time estimate.

At step 112, the variable ACC is iteratively acquired according to the equation: ACC=((ACCₚᵣₑᵥᵢₒᵤₛ)*(1−K))+Iₜ. For the first iteration, the variable ACCₚᵣₑᵥᵢₒᵤₛ may be set to zero. The variable K is a battery constant which can be obtained according to the equation K=1−EXP((−1*(sample rate)/(B_{tc})). The variable B_{tc} is a battery time constant which can be obtained according to the equation B_{tc}=C₁*R₁. An exemplary method for estimating the battery time constant B_{tc} will hereinafter be described in detail. At step 114, the method 100 delays or waits a predetermined amount of time. According to one embodiment, the duration of the delay at step 114 is approximately 51 seconds. After completing step 114, the method 100 returns to step 102.

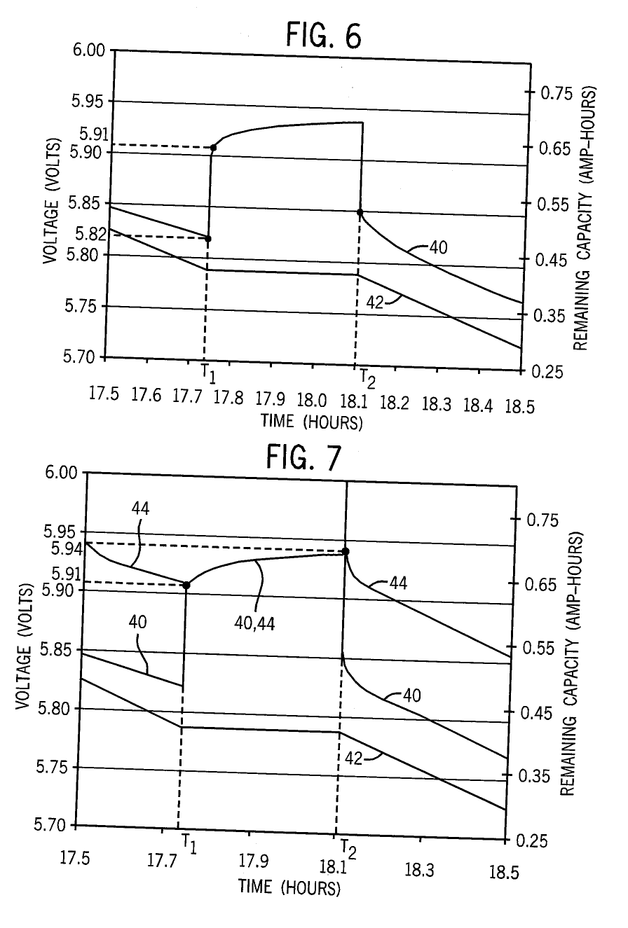

An exemplary method for calculating or estimating each of the variables in the equation Vₛ=Vₜ−(R₂*Iₜ)−(ACC*R₁*(1/B_{tc}) of step 106 will now be described in the order in which they appear. The variable Vₜ may be measured by the controller 14 (shown in FIG. 1) at the terminals 22, 24 in a known manner. The variable R₂ may be obtained from the battery manufacturer or may be estimated by measuring the generally instantaneous change in battery terminal voltage associated with the application or removal of a known load. An exemplary method for estimating R₂ will hereinafter be described with respect to FIG. 6. The variable Iₜ may be measured by the controller 14 at the terminals 22, 24 in a known manner. The variable ACC is calculated in the manner described with respect to step 112 of the method 100

The variable R₁ and the battery time constant B_{tc} may be obtainable from the battery manufacturer or may be estimated by removing a load and curve fitting the resultant slope of a voltage vs. time plot. An exemplary method for calculating the variables R₁, R₂ and the battery time constant B_{tc} will now be described with respect to FIGS. 6-8.

Referring now to FIG. 6, a load in the form of a 0.29 amp discharge current was applied to a sample battery (not shown) similar to the battery 12 (shown in FIG. 1). At time T₁ the 0.29 amp discharge current was removed from the sample battery and at time T₂ the 0.29 amp discharge current was re-applied to the sample battery. The curve 40 represents the sample battery's terminal voltage versus time in response to the application of the previously described discharge sequence. The curve 42 represents the sample battery's remaining capacity versus time in response to the application of the previously described discharge sequence. It can be seen that the slope of the battery terminal voltage curve 40 differs from that of the remaining capacity curve 42, particularly between time periods T₁ and T₂, because the battery terminal voltage curve 40 does not account for the variables R₁, R₂ and the battery time constant B_{tc} (shown in FIG. 3).

As previously indicated, the variable R₂ (shown in FIG. 3) may be estimated by measuring the generally instantaneous change in battery terminal voltage associated with the application or removal of a known load. It can be seen with reference to FIG. 6 that, at time T₁, the terminal voltage (represented by curve 40) increases from approximately 5.82 volts to approximately 5.91 volts in response to the removal of the 0.29 amp discharge current. Therefore, the variable R₂ can be calculated using Ohm's law according to the equation R₂=ΔV/I=(5.91−5.82)/0.29=0.31 ohms.

FIG. 7 shows a plot of the previously described curves 40 and 42, and a curve 44. The curve 44 comprises the battery terminal voltage and a correction factor accounting for the resistance R₂ (shown in FIG. 3). More precisely, the curve 44 is a plot of the quantity (Vₜ−(R₂*Iₜ)) versus time in response to the application of the battery discharge sequence described with respect to FIG. 6.

It can be seen that by incorporating a correction factor adapted to account for the resistance R₂, the slope of curve 44 more closely approximates that of the remaining capacity curve 42. The slope of the curve 44 between times T₁ and T₂ is, however, inconsistent with that of the remaining capacity curve 42 because the curve 44 does not account for the resistance R₁ and the battery time constant B_{tc} (shown in FIG. 3).

An estimate of the variable R₁ can be obtained using the curve 44 by identifying the change in voltage over time associated with the application or removal of a known load. This estimate is predicated on the assumption that the internal battery capacitance C₁ (shown in FIG. 3) will eventually reach voltage level Vₛ such that, over a sufficiently long period of time, the change in voltage is attributed exclusively to the resistance R₁. For example it can be seen with reference to FIG. 7 that, during time interval T₁-T₂, the curve 44 increases from 5.91 volts to 5.94 volts in response to the removal of the 0.29 amp discharge current. This change in voltage over time associated with the removal of a known load can be implemented in combination with Ohm's law to calculate R₁ according to the equation: R₁=ΔV/I=(5.94−5.91)/0.29=0.1 ohms.

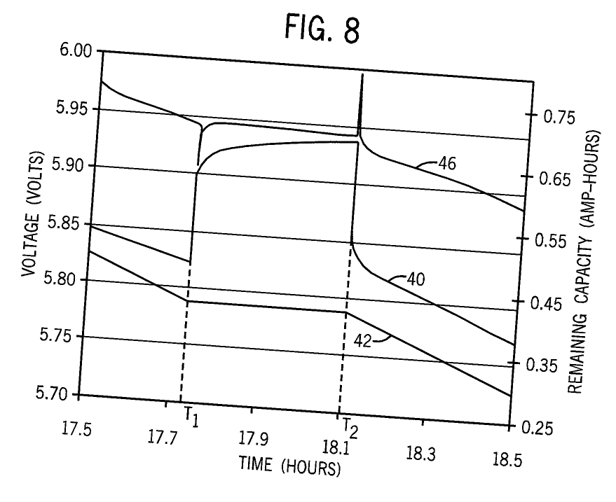

FIG. 8 shows a plot of the previously described curves 40 and 42, and a curve 46. The curve 46 represents an estimate of the battery's internal voltage source (Vₛ) based on the battery terminal voltage; a first correction factor accounting for the resistance R₂ (shown in FIG. 3); and a second correction factor accounting for both the resistance R₁ and the battery time constant B_{tc}. More precisely, the Vₛ curve 46 is a plot of the quantity (Vₜ−(R₂*Iₜ)−(ACC*R₁*(1/B_{tc})) versus time in response to the application of the battery discharge sequence described with respect to FIG. 6.

It should be appreciated that the equation defining the curve 46 includes only one unknown variable (the battery time constant B_{tc}). This unknown variable can be estimated by a trial and error process and by curve fitting the slope of the resultant Vₛ curve. In other words, the estimated B_{tc} variable is that which produces a Vₛ curve having a slope most closely matching that of the curve 42. According to the example illustrated in FIG. 8, the B_{tc} estimate producing the Vₛ curve 46 is 2,000 seconds. As the slope of the curve 46 is highly similar to the slope of the curve 42, it can be assumed that the estimated B_{tc} value of 2,000 is accurate.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

We claim:

1. A battery system comprising:
a battery; and
a controller operatively connected to the battery, said controller being configured to estimate a battery state of charge based on a history of the battery current such that the battery state of charge estimate is obtainable during the battery's course of use.

2. The battery system of claim 1, wherein the controller is further configured to implement a recently acquired battery terminal voltage measurement to estimate the battery state of charge.

3. The battery system of claim 1, wherein the controller is further configured to implement a recently acquired battery terminal current measurement to estimate the battery state of charge.

4. The battery system of claim 1, wherein the controller is further configured to estimate the battery state of charge based on an estimated internal resistance of the battery.

5. The battery system of claim 1, wherein the controller is further configured to estimate the battery state of charge based on an estimated internal capacitance of the battery.

6. The battery system of claim 1, wherein the controller is further configured to estimate a battery run-time based on the battery state of charge.

7. The battery system of claim 1, wherein the battery comprises a lead-acid battery.

8. The battery system of claim 1, wherein the battery comprises a rechargeable battery adapted for attachment to a remotely located power source.

9. The battery system of claim 1, wherein the battery comprises a primary non-rechargeable battery.

10. A patient monitoring system comprising:
a battery;
a patient monitoring device operatively connected to the battery; and
a controller operatively connected to the battery, said controller being configured to estimate a battery state of charge based on a recently acquired battery terminal voltage measurement; a recently acquired battery terminal current measurement; and a history of the battery current;
wherein the battery state of charge estimate is obtainable during the battery's course of use.

11. The patient monitoring system of claim 10, wherein the battery comprises a lead-acid battery.

12. The patient monitoring system of claim 10, wherein the patient monitoring device comprises a portable patient monitoring device.

13. The patient monitoring system of claim 10, wherein the controller is further configured to estimate the battery state of charge based on an estimated internal resistance of the battery.

14. The patient monitoring system of claim 10, wherein the controller is further configured to estimate the battery state of charge based on an estimated internal capacitance of the battery.

15. The patient monitoring system of claim 10, wherein the controller is further configured to estimate a battery run-time based on the battery state of charge.

16. A method for estimating the state of charge of a battery comprising:
obtaining a recently acquired battery terminal voltage measurement;
obtaining a recently acquired battery terminal current measurement;
obtaining a history of the battery current;
estimating a source voltage based on the recently acquired battery terminal voltage measurement, the recently acquired battery terminal current measurement, and the history of the battery current; and
estimating a battery state of charge based on the source voltage such that the battery state of charge is obtainable during the battery's course of use.

17. The method of claim 16, further comprising estimating battery run-time based on the battery state of charge.

18. The method of claim 16, wherein said estimating a source voltage comprises estimating a source voltage based on an internal resistance of the battery.

19. The method of claim 16, wherein said estimating a source voltage comprises estimating a source voltage based on an internal capacitance of the battery.
